(19) United States
(12) Patent Application Publication
(10) Pub. No.: US 2013/0128463 A1
(43) Pub. Date: May 23, 2013

(54) HEAT SINK ASSEMBLY

(71) Applicant: FENG-CHI YANG, Tu-Cheng (TW)

(72) Inventor: FENG-CHI YANG, Tu-Cheng (TW)

(73) Assignee: HON HAI PRECISION INDUSTRY CO., LTD., Tu-Cheng (TW)

(21) Appl. No.: 13/561,459

(22) Filed: Jul. 30, 2012

(30) Foreign Application Priority Data
Nov. 21, 2011 (CN) 201110370599.4

(51) Int. Cl. H05K 7/20

(52) U.S. Cl. 361/719

(57) ABSTRACT

A heat sink assembly is for attachment to a chip of a printed circuit board. The heat sink assembly includes a heat sink, a frame and a plurality of fasteners. The heat sink is attached on the chip, and includes a base and a plurality of fins. The fins define a plurality of cutouts. The frame includes beams, locking portions, and extensions. The locking portions extend from the beams. The extensions perpendicularly extend from the locking portions, and are received in the cutouts. The fasteners extend through the extensions to hold the base against the chip.

### BACKGROUND

1. Technical Field

The disclosure generally relates to a heat sink assembly.

2. Description of Related Art

Heat sinks are usually positioned on heat generating electrical components. A heat sink assembly may include a heat sink and a base. To secure the heat sink on an electrical component such as CPU, the base is secured onto the CPU by screws.

However, since the force from the screws is applied on the base, the base distorts towards the CPU after a period of time. A space begins to grow between the base and the CPU, greatly affecting the dissipating effect of the heat sink.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary heat sink assembly. Moreover, in the drawings, like reference numerals designate corresponding parts throughout the several views. Wherever possible, the same reference numbers are used throughout the drawings to refer to the same or like elements of an embodiment.

FIG. 1 is an exploded view of a heat sink assembly according to an exemplary embodiment.

FIG. 2 is an isometric view of the assembled heat sink assembly shown in FIG. 1.

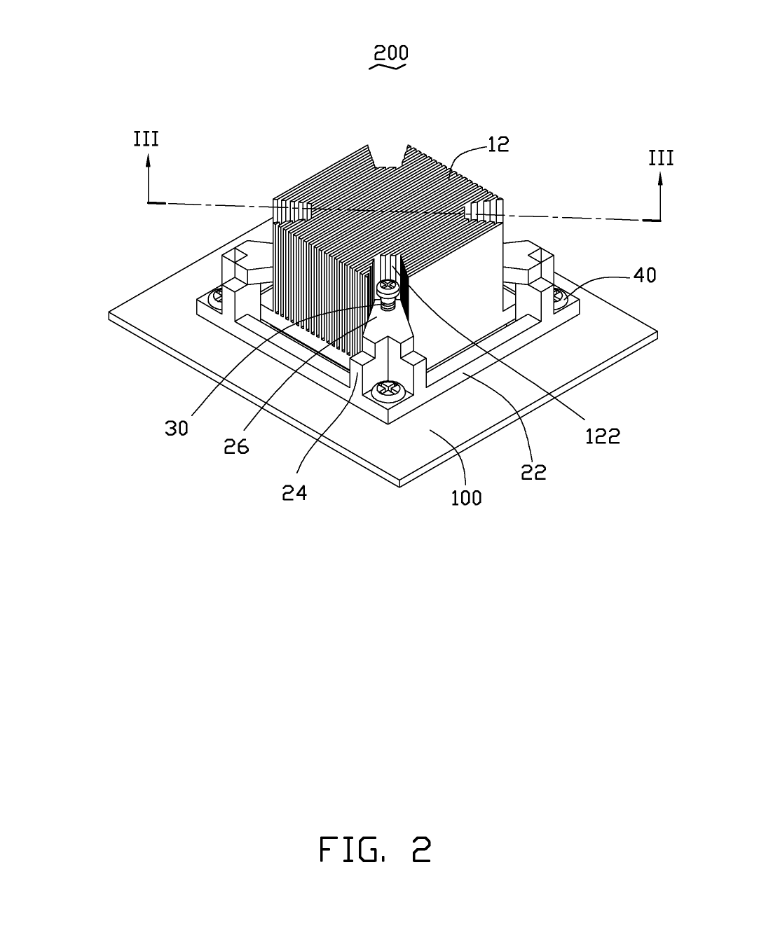

FIG. 3 is a cross-sectional view of the heat sink assembly shown in FIG. 2 taken along line III-III.

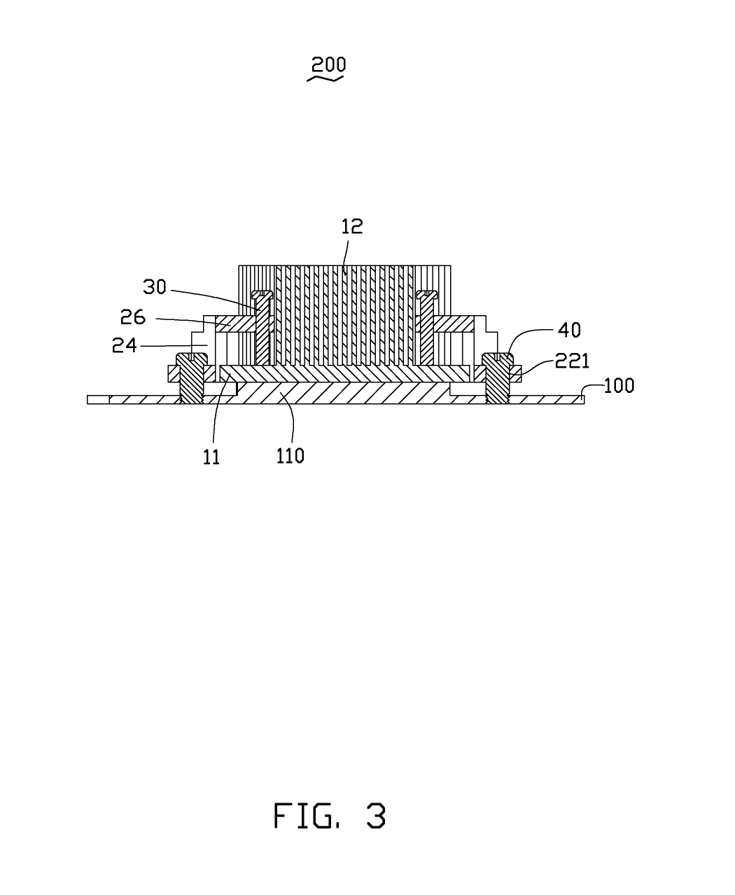

### DETAILED DESCRIPTION

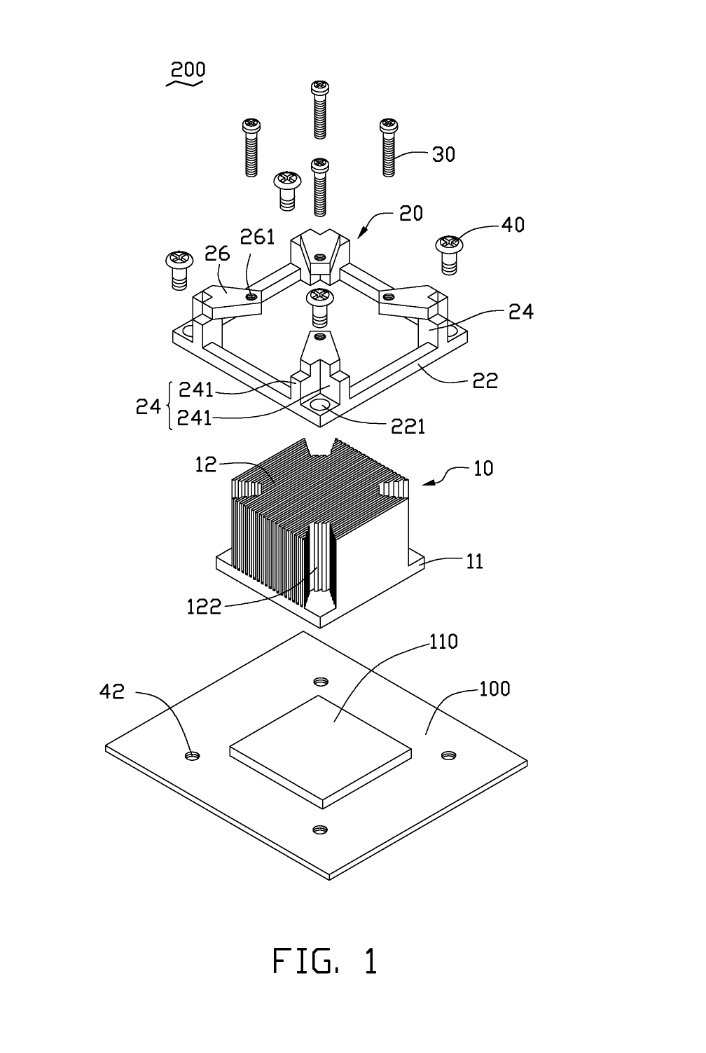

Referring to FIG. 1, a heat sink assembly 200 is to be attached to a printed circuit board 100 in an exemplary embodiment. A chip 110 (e.g. a CPU) is positioned on the printed circuit board 100. A plurality of fixing holes 42 are defined in the printed circuit board around the chip 110. The heat sink assembly 200 is configured for dissipating heat from the chip 110 disposed on the printed circuit board 100. The heat assembly 200 includes a heat sink 10, a frame 20, a plurality of first fasteners 30 and a plurality of second fasteners 40.

The heat sink 10 includes a base 11 and a plurality of fins 12. The fins 12 protrude from the base 11, and are parallel with each other. The arrangement of all the fins 12 together substantially forms a cube. Each corner of the cube formed by the fins 12 is cut so as to define a cutout 122. Each cutout 122 communicates with two ends of the fins 12, and one portion of the base 11 under the cutout 122 is exposed from the fins 12.

The frame 20 includes a plurality of beams 22, a plurality of locking portions 24, and a plurality of extensions 26. In this exemplary embodiment, there are four beams 22. The beams 22 perpendicularly connect to each other to form a square or rectangular frame. Each corner of the beams 22 defines a through hole 221 and has a corresponding locking portion 24. Each locking portion 24 is made of two fixing plates 241 perpendicular to each other. One end of the fixing plates 241 is integrally formed with and perpendicularly extends from the beams 22. Each extending portion 26 perpendicularly extends from an opposite end of the fixing plates 241, and is parallel with the beams 22. Each extending portion 26 defines a screw hole 261.

The first fasteners 30 engage in the screw holes 261 to fix the frame 20 on the heat sink 10. The second fasteners 40 engage the through holes 221 and the fixing holes 42 to fix the frame 20 on the printed circuit board 100. In this exemplary embodiment, the first fasteners 30 and the second fasteners 40 are screws.

To assemble the heat sink 10 to the printed circuit board 100, the base 11 of the heat sink 10 is attached on the chip 110. The frame 20 surrounds the fins 12. The beams 22 abut against the printed circuit board 100, and the extensions 26 extend into the cutouts 122. The first fasteners 30 extend through the screw holes 261 of the extensions 26, and hold the base 11 against the chip 110. Finally, the second fasteners 40 extend through the through holes 221 and are fixed into the fixing holes 42 on the printed circuit board 100 to secure the frame 20 on the printed circuit board 100.

A significant advantage of the heat sink assembly 200 is that the heat sink assembly 200 adopts the frame 20 to lock the heat sink 10, and the first fasteners 30 do not directly fix the heat sink 10 on the chip 110 and the printed circuit board 100. This effectively prevents the force from the fasteners from being directly applied to the base 11 of the heat sink 10, and thereby reduces the deforming possibility of the base 11. Additionally, the base 11 of the heat sink 10 can be tightly pressed against the chip 110 by the first fasteners 30 for greatly improving the dissipating effect of the heat sink 10.

It is to be understood, however, that even through numerous characteristics and advantages of the disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A heat sink assembly attached to a chip of a printed circuit board, comprising:
a heat sink attached on the chip, the heat sink including a base and a plurality of fins, the fins defining a plurality of cutouts;
a frame including a plurality of beams, a plurality of locking portions, and a plurality of extensions, the locking portions extending from the beams, the extensions perpendicularly extending from the locking portions, the extensions received in the cutouts; and
a plurality of fasteners extending through the extensions to abut the base on the chip.

2. The heat sink assembly as claimed in claim 1, wherein the fins substantially form a cube, each corner of the cube formed by the fins is cut to define one of the cutouts, each cutout communicates with two ends of the fins, and one portion of the base under the cutouts is exposed from the fins.

3. The heat sink assembly as claimed in claim 2, wherein there are four beams, the beams perpendicularly connect to each other to surround a rectangle, each corner of the beams defines a through hole and has one of the locking portions.

4. The heat sink assembly as claimed in claim 1, wherein each locking portion is made of two fixing plates perpendicularly each other, one end of the fixing plates is integrally formed with and perpendicularly extends from the beams, each extending portion perpendicularly extends from an opposite end of the fixing plates, and is parallel with the beams.

5. The heat sink assembly as claimed in claim 4, wherein each extending portion defines a screw hole, the fasteners extend through the screw holes of the extensions, and abut the base on the chip.

6. A heat sink assembly comprising:
a heat sink including a base and a plurality of fins, the fins defining a plurality of cutouts;
a frame including a plurality of beams, a plurality of locking portions, and a plurality of extensions, the locking portions extending from the beams, the extensions perpendicularly extending from the locking portions, the extensions received in the cutouts; and
a plurality of fasteners extending through the extensions to abut the base.

7. The heat sink assembly as claimed in claim 6, wherein each locking portion is made of two fixing plates perpendicularly each other, one end of the fixing plates is integrally formed with and perpendicularly extends from the beams, each extending portion perpendicularly extends from an opposite end of the fixing plates, and is parallel with the beams.

8. The heat sink assembly as claimed in claim 7, wherein there are four beams, the beams perpendicularly connect to each other to surround a rectangle, each corner of the beams defines a through hole and has one of the locking portions.

9. The heat sink assembly as claimed in claim 6, wherein each extending portion defines a screw hole, the fasteners extend through the screw holes of the extensions, and abut the base.
